(19) United States
(12) Patent Application Publication
(10) Pub. No.: US 2025/0225825 A1
(43) Pub. Date: Jul. 10, 2025

(54) METHOD FOR MONITORING A MOTOR VEHICLE ELECTRICAL SYSTEM

(71) Applicant: Robert Bosch GmbH, Stuttgart (DE)

(72) Inventors: Lars Braun, Luessow (DE); Manuel Eder, Weinstadt (DE); Michael Muerken, Gaggenau-Freiolsheim (DE)

(21) Appl. No.: 18/850,868

(22) PCT Filed: Mar. 6, 2023
(86) PCT No.: PCT/EP2023/055544

§ 371 Date: Sep. 25, 2024

(30) Foreign Application Priority Data
May 16, 2022 (DE) 10 2022 204 748.6

(51) Int. Cl. G07C 5/08; B60R 16/03; G01R 19/25

(52) U.S. Cl. CPC G07C 5/0808; B60R 16/03; G01R 19/2513; G07C 5/0816

(57) ABSTRACT

Methods for monitoring a motor vehicle electrical system. At least one power distributor is provided, via which at least one safety-relevant consumer is supplied with a supply voltage and via which non-safety-relevant consumers are supplied. The power distributor is supplied by at least one stored energy source. A measure for the voltage applied at least to the safety-relevant consumer is ascertained, wherein, on that basis, an undervoltage at the safety-relevant consumer is ascertained in dependence on a limit value. A reduction measure for a disconnection or downgrading of at least one non-safety-relevant consumer required to increase the voltage applied to the safety-relevant consumer is determined in dependence on the undervoltage, and a selection of the non-safety-relevant consumer to be disconnected or to be downgraded is made based on the reduction measure.

### FIELD

The present invention relates to a device for monitoring a motor vehicle electrical system.

### BACKGROUND INFORMATION

German Patent Application No. DE 10 2018 212 369 A1 describes a method for monitoring an energy supply in a motor vehicle, wherein in an electrical subsystem at least one stored energy source device supplies a plurality of preferably safety-relevant consumers with energy. At least one measured variable of a stored energy source and/or of at least one consumer is detected, wherein at least one wiring harness model is provided which maps the electrical subsystem. A parameter estimator is provided which estimates at least one parameter of the wiring harness model using the measured variables.

German Patent Application No. DE 10 2018 212 777 A1 describes a method for monitoring an electrical system of a motor vehicle. This involves a simulation to check which safe-stop scenario is available under the current battery and electrical system status. Furthermore, corresponding measures in the electrical system are proposed and the analysis of the direct impact of these measures on the availability of the various scenarios is ascertained.

German Patent Application No. DE 10 2020 212 414 A1 describes a method for monitoring a motor vehicle electrical system, wherein at least one safety-relevant consumer and possibly further consumers are supplied by a stored energy source, wherein at least one electrical system model is provided which maps the safety-relevant consumer and corresponding lines with associated line resistances and connection to the stored energy source, comprising the following steps: providing a current profile or power profile which is expected to be necessary at least for a specific maneuver of the motor vehicle involving the safety-relevant consumer and which can include a base load of at least one further consumer; ascertaining a predicted parameter of the stored energy source using the current profile or power profile; ascertaining a predicted parameter of the safety-relevant consumer using a current profile or power profile with which the safety-relevant consumer is expected to be charged, the associated line resistance and the predicted parameter of the stored energy source; evaluating the predicted parameter of the safety-relevant consumer.

An object of the present invention is to further increase the availability, in particular in electrical systems with high safety requirements, while minimizing the loss of comfort. This problem may be solved according to certain features of the present invention.

### SUMMARY

A method according to present invention may have the advantage, on the one hand, that a sufficient voltage supply for safety-relevant consumers can be ensured with a high degree of reliability, wherein, on the basis of the more precise ascertainment of a reduction measure, only really necessary non-safety-relevant consumers are specifically downgraded or disconnected. This means that as many non-safety-relevant consumers as necessary and as few as possible are disconnected from the energy supply. Due to the more precise ascertainment of the reduction measure and the undervoltage, it can be precisely ensured that the measure taken effectively reduces the undervoltage, which has also been ascertained in the desired manner and that the safety-relevant consumers are then adequately supplied again. Due to individual ascertainment of the voltage drop at the safety-relevant consumer, tolerances with respect to undervoltage can be better exploited, so that a potentially premature disconnection of non-safety-relevant consumers or consumer groups is minimized, but without endangering the supply to safety-relevant consumers. This increases the availability of non-safety-relevant consumers.

In an expedient development of the present invention, a point in time of disconnection or a trigger for disconnecting or downgrading at least one of the non-safety-relevant consumers is generated when the voltage applied to the safety-relevant consumer falls below the limit value for a certain time period, preferably in the range between 1 ms and 500 ms. In practice, this allows the corresponding voltage requirements to be individually adapted to the respective safety-relevant consumers by a corresponding selection of the limit values or by corresponding time periods being individually tailored to the respective properties of the safety-relevant consumers. The corresponding time interval between 1 ms and 500 ms makes it clear that the method is not intended for line, component or part protection, where overcurrent disconnection may be necessary in time ranges of less than 10 μs. In contrast to traditional electrical system interventions for voltage support greater than 500 ms, the selected time range takes into account the stricter safety requirements for safety-relevant consumers.

In an expedient development of the present invention, it is provided that the measure for the voltage applied to the safety-relevant consumer is ascertained from the supply voltage at the power distributor and a voltage drop on a line path between the power distributor and the safety-relevant consumer. It is precisely by taking into account the voltage drop along the line path that a particularly precise and accurate prediction of a possible undervoltage can be realized, which means that non-safety-relevant consumers can be disconnected or downgraded in a targeted and needs-oriented manner. As a rule, non-safety-relevant consumers can be disconnected later than would be the case with a disconnection with the otherwise usual high safety margins.

In an expedient development of the present invention, it is provided that the voltage drop on the line path between the power distributor and the safety-relevant consumer can be ascertained with the aid of a resistance of the respective line path and the current flowing through the safety-relevant consumer. The corresponding measured variables, in particular of the current, are usually present in the power distributor in any event, for example due to safety functions relating to overcurrent disconnection or the like, so that the voltage drop at the safety-relevant consumer can thereby be easily ascertained.

In an expedient development of the present invention, the reduction measure, in particular the reducing current, is ascertained in dependence on a resistance of a line path connecting the stored energy source and the power distributor and/or in dependence on an internal resistance of the stored energy source. On the other hand, the precision of the downgrading or disconnection is increased because additional parameters, which can also change significantly over the service life of the stored energy source or electrical system, are taken into account.

In an expedient development of the present invention, a number of non-safety-relevant consumers to be disconnected is ascertained depending on the reduction measure. In contrast to what is often the case, not all non-safety-relevant consumers are disconnected in the event of a supply shortfall, but only the exact number required for this. This further increases comfort for the user, as there is no need to disconnect unnecessary, non-safety-relevant consumers.

In an expedient development of the present invention, the reduction measure is ascertained in such a way that the supply voltage is increased at least by the undervoltage. This precise increase prevents unnecessary excessive voltage increases, which further increases comfort.

In an expedient development of the present invention, the limit value changes in dependence on a time period for which the voltage applied to the safety-relevant consumer falls below the corresponding limit value, in particular increasing with an increasing time period. This makes it possible to counteract in a targeted and timely manner particularly critical situations, which would result in a long-term failure to provide an adequate supply voltage.

In an expedient development of the present invention, the reduction measure is ascertained using a resistance of a line path to the stored energy source and/or to an alternative energy source and/or an internal resistance of the stored energy source and/or in dependence on a previously specified reduction measure and/or in dependence on a resistance of a line path to the stored energy source and/or to an alternative energy source ascertained by a model or diagnosis and/or in dependence on an internal resistance of the stored energy source ascertained by a model or diagnosis. Precision can thus be further increased. In particular, by using a model, the aging state of the electrical system components can be predicted relatively accurately and used as the basis for a corresponding more precise ascertainment of the reduction measure.

One expedient development of the present invention is characterized in that it is ascertained when the measure for the voltage applied to the safety-relevant consumer reaches the limit value and that, from the time the limit value is reached, a time period is detected during which the limit value is undershot, wherein the detected time period is compared with a time period assigned to the limit value and, when the assigned time period is reached, a trigger is generated for initiating a disconnection or downgrading of at least one non-safety-relevant consumer. This enables a simple implementation of a limit value dependent on the time period, which enables an easy adaptation to the respective safety-relevant consumer.

In an expedient development of the present invention, it is provided that the measure for the voltage applied at least to the safety-relevant consumer is ascertained by measuring this voltage at the safety-relevant consumer and/or by using a current flowing through the safety-relevant consumer and/or by measuring the supply voltage and/or by taking into account a resistance, in particular a worst-case value of the resistance or a resistance estimated by a model, of a line path between the power distributor and the safety-relevant consumer and/or in dependence on a worst-case value of a voltage drop at the resistance. On the one hand, the precision of the evaluation can be further increased by suitable measures such as measuring the voltage directly at the safety-relevant consumer or the current flow through the safety-relevant consumer. On the other hand, certain worst-case values can further simplify the ascertainment. By using a model even for ascertaining the voltage at the safety-relevant consumer, the corresponding aging states of the electrical system components can be reliably mapped. The precision of ascertainment increases.

In an expedient development of the present invention, it is provided that the trigger and/or the undervoltage is ascertained by the safety-relevant consumer and/or that the safety-relevant consumer transmits the trigger and/or the undervoltage and/or the measured voltage drop at the safety-relevant consumer, in particular to the power distributor. This allows a quick and accurate evaluation already to be carried out in the safety-relevant consumer, which is usually equipped with high computing power in any event, and relieves the power distributor of such tasks. The volume of communication can also be reduced, since a disconnect signal is only sent when there is an impending undervoltage.

In an expedient development of the present invention, it is provided that a selection of the non-safety-relevant consumer to be disconnected or downgraded is made based on the currents flowing through the respective non-safety-relevant consumers, in particular that the non-safety-relevant consumer with a maximum current flow or with a current flow that exceeds a certain limit value is disconnected or downgraded. This ensures that the disconnected non-safety-relevant consumers actually cause the desired voltage increase. In addition, the proposed measure ensures that only a small number of the non-safety-relevant consumers that are actually needed need to be disconnected.

In an expedient development of the present invention, it is provided that a further non-safety-relevant consumer is disconnected until the reduction measure has been reached. This makes the selection particularly easy to implement, and ensures that the desired voltage increase is achieved.

In an expedient development of the present invention, it is provided that the respective current flowing through the non-safety-relevant consumer is linked to a weighting factor specific to the respective non-safety-relevant consumer and the respective linked values are used to select the non-safety-relevant consumer to be disconnected or downgraded. It is particularly expediently provided that the non-safety-relevant consumers are in each case assigned a weighting or priority value and that the selection of the respective consumers to be disconnected or downgraded is carried out by optimizing the linked weightings or priority values. By means of an appropriate weighting, the consumers can be prioritized differently in order to keep the loss of comfort for the user as low as possible.

Further expedient developments of the present invention can be found in the disclosure herein.

### BRIEF DESCRIPTION OF THE DRAWINGS

FIG. 1 shows an electrical system with a power distributor, according to an example embodiment of the present invention.

FIG. 2 shows an alternative exemplary embodiment of an electrical system with a power distributor and further distributors, according to the present invention.

FIG. 3 shows a block diagram for the implementation of the various sub-methods, according to an example embodiment of the present invention.

FIG. 4 shows an exemplary voltage-time diagram with corresponding undervoltage ranges, according to an example embodiment of the present invention.

### DETAILED DESCRIPTION OF EXAMPLE EMBODIMENTS

The present invention is illustrated schematically on the basis of an exemplary embodiment and will be described in detail below with reference to the figures.

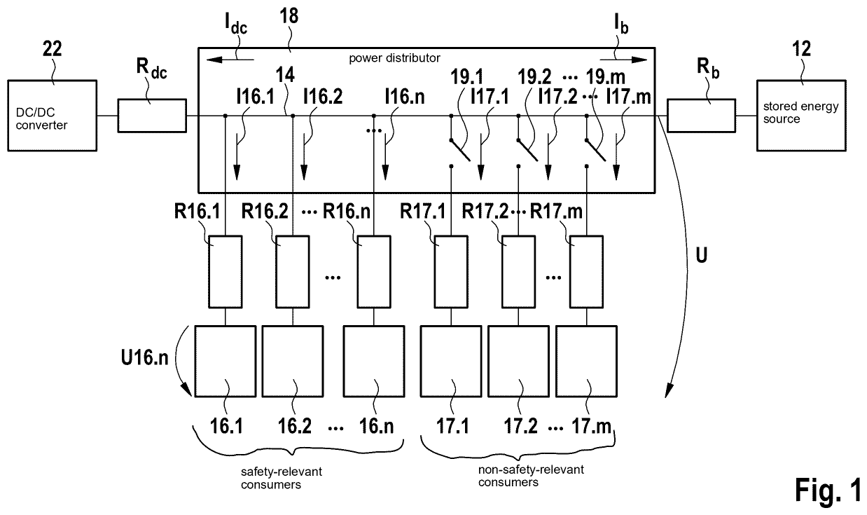

FIG. 1 shows an electrical subsystem, in particular in a motor vehicle, which comprises a power distributor 18. The power distributor 18 is supplied with energy via a stored energy source 12, in particular a battery. For this purpose, the stored energy source 12 is connected to a busbar 14 which runs at least partially within the power distributor 18. Between the power distributor 18 and the stored energy source 12, a resistor Rb is indicated, which represents the resistance in the supply line to the stored energy source 12, in particular the battery. For a possibly redundant supply of the power distributor 18, the busbar 14 of the power distributor 18 can be connected to a further power supply at the other input, indicated in the exemplary embodiment by the provision of a DC/DC converter 22. The DC/DC converter 22 establishes the connection to a further electrical subsystem, which can, for example, comprise a higher or lower or similar voltage level. Between the power distributor 18 and the DC/DC converter 22, a resistor Rdc is again indicated schematically, which represents the resistance in the supply line from the power distributor 18 to the DC/DC converter 22.

Connected to the power distributor 18 are n safety-relevant consumers 16.1, 16.2, . . . , 16.n and m non-safety-relevant consumers 17.1, 17.2, . . . , 17.m. The safety-relevant consumers 16.n can be specially protected, for example against overcurrents, by switching means, which are not shown for reasons of clarity. The non-safety-relevant consumers 17.m can in each case be controlled by switching means 19 (19.1, 19.2, . . . , 19.m), in particular disconnected or downgraded. These switching means 19 are arranged in the power distributor 18. The switching means 19 are preferably semiconductor switches such as MOSFETs etc. In the power distributor 18, the voltage U on the busbar 14 is measured. In addition, a current measurement is provided in the power distributor 18. In the exemplary embodiment, each current I16.n flowing through the respective safety-relevant consumer 16.n is detected. Optionally, any current I17.m flowing through the respective non-safety-relevant consumer 17.m can be detected. Optionally, the respective applied voltage U16.n can be measured at the respective safety-relevant consumer 16.n, in particular in relation to earth or ground GND. Depending on the location of the evaluation, the ascertained or measured applied voltage U16.n can also be transmitted to the power distributor 18 or other control devices via a communication system, for example a bus system such as a CAN bus or the like. Alternatively, the evaluation could be carried out in the safety-relevant consumer 16.n itself.

Between the power distributor 18 and the respective safety-relevant consumer 16.n, a resistor R16.1, R16.2, . . . , R16.n in each case is shown, which represents the resistance of the respective line path between the power distributor 18 and the respective consumer 16.n. Between the power distributor 18 and the respective non-safety-relevant consumer 17.m, a resistor R17.1, R17.2, . . . , R17.m in each case is shown, which represents the resistance of the respective line path between the power distributor 18 and the respective non-safety-relevant consumer 17.m.

A sensor (not shown), preferably a battery sensor, could be provided at the stored energy source 12 in order to detect further parameters of the stored energy source 12. In this sensor, for example, corresponding parameters of the stored energy source 12 such as the internal resistance Ri, the state of charge SOC or the like could be ascertained based on the state variables of the stored energy source 12 and of an associated model. The safety-relevant consumers 16 are special consumers with high demands or a high protection requirement which are generally referred to as safety-relevant consumers 16. For example, in this case an electrical steering system and/or a brake system are examples of such components which it is imperative to supply with power in order to ensure the steering and/or braking of the vehicle in the event of a fault.

Likewise, the power distributor 18 has corresponding processing means, such as the microcontroller, for storing and/or evaluating detected variables. The microcontroller is also able to control corresponding switching means 19 (or the switching means (not specifically shown) for protecting the safety-relevant consumers 16). Alternatively, the evaluation could also take place in another control device.

The safety-relevant consumers 16 supplied by the power distributor 18 could, for example, include safety-relevant vehicle functions such as braking, steering, etc., in particular consumers 16 with high demands with regard to protection requirements. In general, safety-relevant consumers 16 are consumers particularly worthy of protection, which are necessary, for example, for maintaining certain emergency functions. In addition to the described functions such as steering and braking, the functions can also be those which, for example after an accident, should still be functional, such as restraint systems, locking systems for opening and closing the vehicle doors, emergency call systems, for example for sending an electronic emergency call, sliding roof functions, lighting or the like.

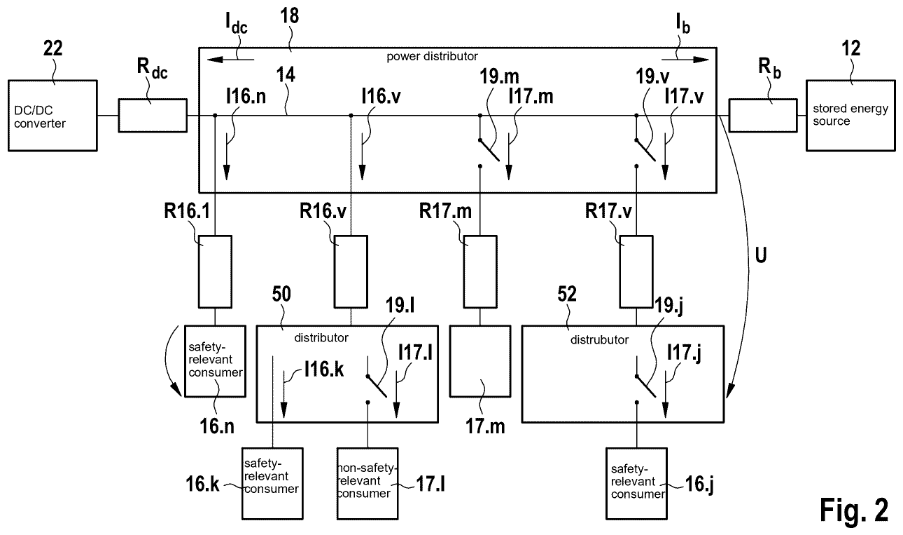

The non-safety-relevant consumers 17.m are typically comfort-related consumers. Comfort-related consumers 17.m can be divided into main and subgroups and thus grouped depending on the application (compare the alternative exemplary embodiment according to FIG. 2 with the other distributors 50, 52). These are those consumers 17 which are not distinguished by a high level of safety relevance or by high demands with regard to a protection requirement.

The exemplary embodiment according to FIG. 2 differs from that according to FIG. 1 in that further distributors 50, 52 are connected to the power distributor 18, via which further consumers 16.k, 17.l, 17.j in each case shown by way of example can be controlled. The distributor 50, to which at least one safety-relevant consumer 16.k is connected, is supplied with a corresponding current I16.v by the power distributor 18 via a line with a line resistance R16.v. In addition, a further distributor 52 is provided, via which only non-safety-relevant consumers 17.j—only a single one being shown by way of example in the exemplary embodiment—can be supplied and disconnected via corresponding switching means 19.j. The further distributor 52 is supplied with a corresponding current I17.v by the power distributor 18 via a line with a line resistance R17.v. The associated non-safety-relevant consumer 17.j is supplied with a current I17.j.

The sub-methods described below can be distributed across different control devices. A disconnection of the non-safety-relevant consumers 17.m can thus also be triggered in other distributors 50, 52 via the corresponding switching means 19.l, 19.j. The signal 40 for disconnecting the consumers 17.l, 17.j could be transmitted via a communication bus and also be commanded in a separate control device such as a so-called vehicle computer. If an undervoltage dU is present at a safety-relevant consumer 16.k, which is in turn supplied by the distributor 50, this distributor 50 can also initiate at the power distributor 18 a disconnection of corresponding non-safety-relevant consumers 17.

By way of example, a battery is described as a possible stored energy source 12 in the exemplary embodiment. Alternatively, however, other stored energy sources suitable for this task can likewise be used, for example on an inductive or capacitive basis, fuel cells, capacitors or the like.

The time range for disconnecting the consumers 17 to be disconnected is in the order of magnitude between 1 ms and 500 ms. The method is not used for protecting cables, components or parts and is therefore not comparable with overcurrent disconnection in the time range of less than 10 μs. In the traditional electrical system, control interventions of the energy management system are to be expected in the time range greater than 500 ms. If necessary, it must be ensured that the variables to be evaluated are detected quickly and/or transmitted quickly to the evaluation unit, such as the power distributor 18.

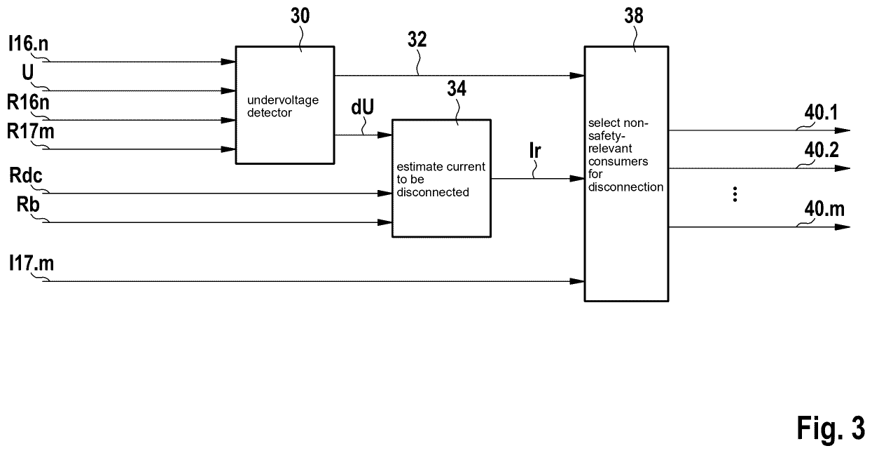

FIG. 3 shows schematically the different blocks 30, 34, 38 with input and output variables. A plurality of the variables described above is fed to an undervoltage detector 30. These are the currents I16.n through the respective safety-relevant consumers 16.n and/or the voltage U on the busbar 14 and/or the respective resistor(s) R16n of the respective line path to the respective safety-relevant consumer 16.n and/or the respective resistor(s) R17.m of the respective line path to the respective non-safety-relevant consumer 17.m. As described below, the undervoltage detector 30 ascertains therefrom at least one trigger 32 and/or the undervoltage dU. The calculation of the undervoltage detector 30 can take place in the power distributor 18 or even in the respective consumer 16.n, 17.m, in particular in the safety-relevant consumer 16.n, but also in a non-safety-relevant consumer 17.m. For undervoltage detector 30, the following method steps can be used individually or in combination. A measure of the voltage U16.n at the respective safety-relevant consumer 16.n can be ascertained using different approaches as follows.

In a first alternative, the voltage U at the busbar 14 is detected. A predefined voltage Uw, which represents the worst case, is subtracted from the voltage U on the busbar 14 in order to take into account the voltage drop across the respective resistor R16.n on the line path to the respective safety-relevant consumer 16.n. This predefined voltage Uw represents a worst-case empirical value that must be taken into account in the worst case scenario. This allows the voltage U16.n at the respective safety-relevant consumer 16.n to be estimated as follows:

$$U 16. n = U - Uw \qquad ( 1 )$$

In a further alternative, the measured voltage U on the busbar 14, the measured currents I16.n through the safety-relevant consumers 16.n and a fixed resistance value R16.n w, which represents the worst case, are used to estimate the magnitude of the voltage drop U16.n at the safety-relevant consumer 16.n. The voltage drop over the line path is calculated from the voltage U on the busbar 14, by a worst-case estimate of the line resistance R16.n w and the current flow I16.n through the respective lines according to Ohm's law:

$$U 16. n = U - I 16. n * R 16. n\_w \qquad ( 2 )$$

In a further alternative, the measured voltage U on the busbar 14, the measured currents I16.n through the safety-relevant consumers 16.n and a respective line resistance R16.n d estimated within the framework of a model are used to estimate the magnitude of the voltage drop U16.n at the safety-relevant consumer 16.n. From the voltage U on the busbar 14, the voltage drop over the line path is calculated with the aid of a diagnostic function (as described, for example, in DE 102018212369 A1, the disclosure of which is fully incorporated by reference) of the line resistance R16.n d and the current flow I16.n through these lines:

$$U 16. n = U - I 16. n * R 16. n\_d \qquad ( 3 )$$

In a further alternative exemplary embodiment, the voltage U16n applied to the safety-relevant consumers 16.n is measured directly within the respective consumer 16.n itself and communicated to the power distributor 18 via a communication interface (CAN, for example):

$$U 16. n = U 16. n via communication means \qquad ( 4 )$$

In a further alternative, a measure of the voltage U16.n applied to the safety-relevant consumer 16.n can be evaluated within the respective consumer 16.n itself. If an impending undervoltage dU is detected, a trigger 34 and/or an undervoltage dU is sent to the power distributor 18 by the function integrated in the respective consumer 16. The undervoltage detection 30 is thus carried out within the consumer 16.n instead of in the power distributor 18:

$$U 16. n = U 16. n in the consumer 16 \qquad ( 5 )$$

The different ways of ascertaining the magnitude of the voltage U16.n applied to the safety-relevant consumer 16.n could be used either alternatively (individually) or also for mutual plausibility checks using at least two, but also a plurality of alternative methods of ascertainment. If the results are implausible, appropriate warnings or countermeasures can be initiated.

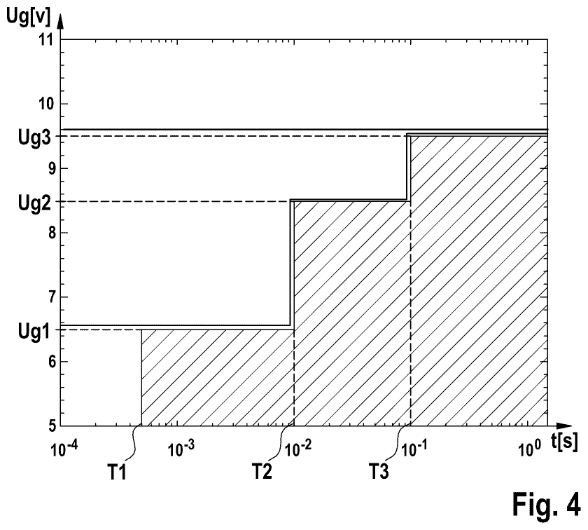

The duration T1, T2, T3 of the applied calculated or measured voltage U16.n is decisive for detecting an impending undervoltage dU and generating a trigger signal 32 which initiates the disconnection 40 or downgrading of non-safety-relevant consumers 17. According to FIG. 4, this is represented by a dynamic voltage limit Ug. The voltage limit Ug thus increases with the increasing duration T of the voltage falling below the voltage limit Ug. In the exemplary embodiment according to FIG. 4, the increase in the voltage limit Ug takes place in steps as the duration T increases. In principle, however, other relationships between the limit value Ug and the maximum permissible time period T for the respective limit value Ug could also be implemented, such as in the form of a continuously or steadily increasing function. The time period T or T1, T2, T3 indicates the maximum duration within which the voltage U16.n of the safety-relevant consumer 16.n must not fall below the associated limit value Ug or Ug1, Ug2, Ug3; otherwise, there will be a risk of undersupply to or failure of the safety-relevant consumer 16.n. Starting from a time period T1, the limit value Ug has a first value Ug1, which remains constant until a further time period T2. The time period T1, for example, lies in the range around 0.5 ms, the further time period T2 is, for example, at 10 ms. The first limit value Ug1 has the lowest value, in relation to the supply voltage (in the exemplary embodiment 12 V); this assumes, for example, a value of around 50% in relation to the supply voltage. In absolute terms, the first limit value Ug1 lies in a range of, for example, 6 V and 7 V, in the exemplary embodiment at 6.4 V. From the time period T2 (for example at 10 ms), the limit value Ug increases to a value for Ug2 of 70% in relation to the supply voltage—in absolute terms, as shown by way of example in FIG. 3, at 8.6 V or in a range for example between 8 and 9 V. From the time period T2, the second limit value Ug2 remains constant up to a time period T3. From a time period T3 (for example at 100 ms), the limit value Ug increases to a value of Ug3 of 80% in relation to the supply voltage—in absolute terms, as shown by way of example in FIG. 3 at 9.6 V or in a range between 9 and 10 V. From the time period T3, the third limit value Ug3 again remains constant.

If the ascertained voltage U16.n threatens to fall below the first limit value Ug1 for the time period T1, a trigger 32 will be generated. If the ascertained voltage U16.n threatens to fall below the second limit value Ug2 for the time period T2, the trigger 32 will be generated. If the ascertained voltage U16.n threatens to fall below the third limit value Ug3 for the time period T3, the trigger 32 will be generated. If the ascertained voltage U16.n falls below one of the limit values Ug, a timer will be started at this point in time. As soon as the time period T assigned to the undershot limit value Ug is reached, the trigger 32 will be generated. In relation to this undershot limit value Ug, the undervoltage dU is ascertained as described below.

With the aid of the ascertained or measured voltage U16.n at the respective safety-relevant consumer 16.n and the dynamic voltage limit Ug; Ug1, Ug2, Ug3, for example as shown in FIG. 3, the differential voltage or undervoltage dU is calculated: dU=Ug−U16.n, wherein the limit value Ug is selected that is closest to the ascertained voltage drop U16.n at the safety-relevant consumer 16.n. For example, if the voltage U16.n is 6 V, the undervoltage dU at the next limit value Ug1 (Ug1=6.4 V) will be 0.4 V. For example, if the voltage U16.n is 8 V, the undervoltage dU at the next limit value Ug2 (Ug2=8.6 V) will be 0.6 V, and so on.

The differential voltage or undervoltage dU serves as an input variable for a block 34 for estimating the current Ir to be disconnected.

The method step or block 34 for estimating the reduction measure, such as the current Ir to be disconnected or reduced, is described in more detail below. In order to stabilize the voltage U (increase by dU) and to comply with the voltage and time limits of the safety-relevant consumers 16.n, it is necessary to disconnect one or more non-safety-relevant consumers 17.m. How many of the non-safety-relevant consumers 17.m have to be disconnected is decided on the basis of the reduction measure (for example, the current 36 to be disconnected) Ir. By how much the current Ir has to be reduced in order to increase the supply voltage U by dU can be deduced via one of the sub-methods described below.

For example, as a possible alternative, a fixed value of the reduction measure or of the current Ir to be disconnected could be implemented. When the trigger 32 is triggered, the current Ir specified here must be disconnected:

$$Ir = const \qquad ( 1 )$$

In a further alternative, the reduction factor Ir is calculated with the aid of the undervoltage dU ascertained by the undervoltage detector 30, the total resistance Rb of the entire path from the stored energy source 12 to the input of the power distributor 18, the resistance Ri for the internal resistance of the stored energy source 12, in particular of the battery, as far as earth or ground. The resistances Rb and Ri mentioned above could be based on the known resistances at the beginning of service life or on corresponding estimates. If the stored energy source 12 is not available as a source or the stored energy source 12 is being charged, the current in the direction of the DC/DC converter 22 will have to be reduced. The reducing current Ir is therefore determined as follows:

$$Ir = dU / ( Rb + Ri ) or Ir = dU / Rdc \qquad ( 2 )$$

With the aid of the undervoltage dU calculated by the undervoltage detector 30, the resistance Rdc d, determined by diagnosis, of the cable harness of the supply line from the DC/DC converter 22 and/or the resistance Rb d, determined by diagnosis, of the cable harness of the supply line to the stored energy source 12 and/or the internal resistance Ri d, determined by diagnosis, of the stored energy source 12, the reduction measure, such as the current Ir to be disconnected, is calculated in a further alternative procedure:

$$Ir = dU / ( Rb\_d + Ri\_d ) or Ir = dU / Rdc\_d \qquad ( 3 )$$

In a further alternative, a reduction factor Ir can also be specified by the energy management system in order to stabilize the voltage accordingly:

$$Ir = Ir via communication system from the energy management system \qquad ( 4 )$$

A further block 38 is used for selecting the non-safety-relevant consumers 17.m for disconnection. For this method step 38, the trigger 32 and/or the current Ir to be disconnected from block 34 and/or the respective currents I17.m flowing through the respective non-safety-relevant consumers 17.m are fed. If in other words the trigger 32 (from block 30) and the current Ir to be disconnected (from block 34) are known, one of the method steps described below will be used to specifically disconnect certain non-safety-relevant consumers 17.m. The disconnection is carried out via corresponding disconnect signals 40.1, 40.2, . . . , 40.m, via which the respective affected switching means 19m can be controlled. The consumers 17.m can be disconnected directly or in a plurality of stages. In the case of gradual disconnection, a defined system response is awaited after a consumer (group) disconnection and, if necessary or if the voltage requirements are not met, the non-safety-relevant consumers 17.m there will be a renewed or a further disconnection. A system response could be an increase in the voltage on the busbar U or a signal from a higher-level system.

In one variant, all non-safety-relevant consumers 17.m can be disconnected. If a corresponding trigger signal 36 is generated and transmitted by the undervoltage detector 30, all non-safety-relevant consumers 17.m will be disconnected. The current Ir to be reduced is not necessary as an input variable.

In a further alternative variant, the criterion used is that of the maximum current that is currently flowing in the respective non-safety-relevant consumers 17.m. Accordingly, the non-safety-relevant consumer 17.max with the maximum current flow I17.max is first disconnected. This continues until the current Ir to be reduced has been reached.

In a further alternative variant, the current I17.m flowing through the non-safety-relevant consumers 17.m can be multiplied by a constant or dynamic weighting factor and kept disconnected according to this weighting score until the current Ir to be reduced has been at least reached. The weighting score can also be independent of the current I17.m. With the aid of the weighting, the optimal consumers 17.m can be disconnected in order to find an optimum between the current Ir to be disconnected and the loss of function of the respective non-safety-relevant consumer 17.m. For this purpose, weighting methods can be used which are based on static or dynamic values or on the current or state of the electrical system components. The non-safety-relevant consumers 17.m to be disconnected or downgraded can be selected, for example, with the aid of an optimization method (for example, optimization problem: binary linear programming). Each consumer path is assigned a weighting which weights the influence that the current I17.m in the respective consumer path has on the system. Firstly, the condition must be met that the sum of the currents (I17.m) of the disconnected consumers 17.m reaches at least the reduction measure Ir. For example, the minimum of the sum of the priority values of the non-safety-relevant consumers 17.m (the higher the prioritization of the non-safety-relevant consumer 17.m, the higher the corresponding priority value) can be used as the optimization target of an optimized consumer disconnection, subject to mandatory compliance with the above reduction condition.

In a further alternative variant, the higher-level vehicle system regularly provides a group of consumers 17.m that can be disconnected. These are then disconnected when the function is executed. Alternatively, even a corresponding grouping of consumers 17.m can be disconnected.

The non-safety-relevant consumers 17.m that have been disconnected must be connected again according to certain criteria. Different criteria can be used here.

In one variant, a reconnection attempt could be made after a specified time. For example, if a reconnection attempt has not been successful after x seconds, i.e. a renewed disconnection occurred, k attempts, for example, can be made to reconnect. Alternatively, an error message can be issued. Reconnection attempts can be discontinued.

A further alternative criterion is to ascertain whether the voltage U is stable for a defined time. If the voltage U is, for example, greater than a threshold value Ug of, for example, 11 V for x seconds, the disconnected non-safety-relevant consumers 17.m can then be connected.

As a further alternative criterion, reconnection can take place after a communication with the energy management system. The energy management system of the entire vehicle or a comparable vehicle system initiates the reconnection of the non-safety-relevant consumers 17.m by means of a communication system, for example a CAN bus. The connection is made individually or interactively and/or grouped.

As part of a further alternative criterion, the disconnected consumers 17.m can be connected again on the basis of the power reserve. This function continuously calculates the minimum power reserve required to connect non-safety-relevant consumers 17.m back to the power supply. Whether a non-safety-relevant consumer 17.m will be connected again is decided either on the basis of a specification by the vehicle system, such as within the framework of energy management and/or on a current value I17.m v previously specified for each consumer 17.m and/or on a dynamically calculated value based on the historical consumer current consumption and/or using a comparable procedure.

The function described is not limited to a specific voltage level U in the electrical system, such as 12 V in the exemplary embodiment. The described method has an interface to the energy management system (not specifically shown) in order to transmit at least one item of feedback information about the disconnected, non-safety-relevant consumers 17.m. In addition, a communication or specification from a higher-level vehicle system (for example, an energy management system as described in the associated sub-methods) is also possible. Due to the execution speed required (between 1 ms and 500 ms), the energy management system cannot perform the function itself. For this reason, the default parameters must be made available before the function is executed in the power distributor 18 or only when reconnecting after an undervoltage has occurred.

1-16. (canceled)

17. A method for monitoring a motor vehicle electrical system, the electrical system including at least one power distributor via which at least one safety-relevant consumer is supplied with a supply voltage and via which non-safety-relevant consumers are supplied, wherein the power distributor is supplied by at least one stored energy source, the method comprising:
ascertaining a measure for a voltage applied at least to the safety-relevant consumer;
ascertaining, based on the ascertained measure for the voltage, an undervoltage at the safety-relevant consumer, depending on a limit value;
determining, depending on the undervoltage, a reduction measure for a disconnection or downgrading of at least one non-safety-relevant consumer required to increase the voltage applied to the safety-relevant consumer; and
selecting a non-safety-relevant consumer to be disconnected or to be downgraded, based on the reduction measure.

18. The method according to claim 17, wherein a point in time of disconnection or a trigger for the disconnecting or downgrading of the at least one of the non-safety-relevant consumers is generated when a voltage drop across the safety-relevant consumer reaches or threatens to reach the limit value for a certain time period.

19. The method according to claim 17, wherein the measure for a voltage drop at the safety-relevant consumer is ascertained from the supply voltage at the power distributor and a voltage drop on a line path between the power distributor and the safety-relevant consumer.

20. The method according to claim 19, wherein the voltage drop on the line path between the power distributor and the safety-relevant consumer is ascertained using a resistance of the line path and a current flowing through the safety-relevant consumer.

21. The method according to claim 17, wherein the reduction measure is ascertained depending on a resistance of a line path connecting the stored energy source and the power distributor and/or depending on an internal resistance of the stored energy source.

22. The method according to claim 17, wherein a number of the non-safety-relevant consumers that are to be disconnected is ascertained depending on the reduction measure.

23. The method according to claim 17, wherein the reduction measure is ascertained in such a way that the supply voltage and/or the voltage applied to the safety-relevant consumer is increased at least by the undervoltage.

24. The method according to claim 17, wherein the limit value changes depending on a time period for which the measure of a voltage drop at the safety-relevant consumer falls below a current limit value, the limit value increasing as the time period increases.

25. The method according to claim 17, wherein the reduction measure, including a current to be reduced: (i) is ascertained using a resistance of a line path to the stored energy source and/or to an alternative stored energy source, and/or (ii) is ascertained using an internal resistance of the stored energy source, and/or (iii) is ascertained depending on a previously specified reduction measure, and/or (iv) is ascertained depending on a resistance of a line path to the stored energy source and/or to an alternative energy source ascertained by a model or diagnosis, and/or (v) is ascertained depending on an internal resistance of the stored energy source ascertained by a model or diagnosis, and/or (vi) is transmitted by an energy management system.

26. The method according to claim 17, wherein it is ascertained when the measure for the voltage drop at the safety-relevant consumer reaches the limit value and from a time the limit value is reached, a time period is detected during which the limit value is undershot, wherein the detected time period is compared with a time period assigned to the limit value and when the assigned time period is reached, a trigger is generated for initiating a disconnection or downgrading of at least one non-safety-relevant consumer.

27. The method according to claim 17, wherein the measure for the voltage applied at least to the safety-relevant consumer is ascertained: (i) by measuring a voltage at the safety-relevant consumer, and/or (ii) by using a current flowing through the safety-relevant consume, and/or (iii) by measuring the supply voltage, and/or (iv) by taking into account a resistance estimated by a model of a line path between the power distributor and the safety-relevant consumer, and/or (iv) depending on a worst-case value of a voltage drop at a resistor of a line path between the power distributor and the safety-relevant consumer.

28. The method according to claim 17, wherein: (i) the ascertaining of a trigger and/or an undervoltage is carried out by the safety-relevant consumer, and/or (ii) the safety-relevant consumer transmits: the trigger and/or the undervoltage and/or the measured voltage at the safety-relevant consumer to the power distributor, and/or (iii) ascertaining the trigger is carried out in different control devices.

29. The method according to claim 17, wherein a selection of the non-safety-relevant consumer to be disconnected or downgraded is made based on currents flowing through each of the non-safety-relevant consumer, wherein that non-safety-relevant consumer with a maximum current flow or with a current flow that exceeds a certain limit value is disconnected or downgraded.

30. The method according to claim 17, wherein a further non-safety-relevant consumer is disconnected until the reduction measure is reached.

31. The method according to claim 17, wherein a respective current flowing through each respective non-safety-relevant consumer is linked to a weighting factor specific to the respective non-safety-relevant consumer and the respective linked values are used for a selection of the non-safety-relevant consumer to be disconnected or downgraded.

32. The method according to claim 17, wherein each of the non-safety-relevant consumers is provided with a weighting or priority value, and the selection of the non-safety-relevant consumer to be disconnected or downgraded is carried out by an optimization of the provided weightings or priority values.
